(19) United States
(12) Patent Application Publication
(10) Pub. No.: US 2008/0157175 A1
(43) Pub. Date: Jul. 3, 2008

(54) Flash Memory Device and Method for Manufacturing Thereof

(76) Inventor: DAE YOUNG KIM, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/863,458

(22) Filed: Sep. 28, 2007

(30) Foreign Application Priority Data
Dec. 27, 2006 (KR) 10-2006-0135760

(51) Int. Cl. H01L 29/788; H01L 21/3205

(52) U.S. Cl. 257/321; 438/591; 257/E21.294; 257/E29.3

(57) ABSTRACT

A flash memory device and method of fabricating the same are provided. A flash memory device includes a tunnel insulating layer on a substrate, a floating gate on the tunnel insulating layer, and ONO layer on the floating gate, and a control gate formed oil the ONO layer. According to an embodiment, the ONO layer of a first oxide layer, a nitride layer, and a second oxide layer is formed from a single oxide film deposited on the floating gate. The nitride layer can be formed between the first oxide layer and the second oxide layer by nitriding a vertically intermediate region of the single oxide film.

### CROSS-REFERENCE TO RELATED APPLICATION

The present application claims the benefit under 35 U.S.C. §119 of Korean Patent Application No. 10-2006-0135760, filed Dec. 27, 2006, which is hereby incorporated by reference in its entirety.

### BACKGROUND

In general, a flash memory device includes a tunnel oxide film on an upper surface of a silicon substrate, a floating gate on the tunnel oxide, an inter-electrode insulating layer on the floating gate, and a control gate electrode on the inter-electrode insulating layer that may be applied with predetermined voltage.

Accordingly, a flash memory device uses two gates, a floating gate and a control gate separated by an inter-electrode insulating layer. The inter-electrode insulating layer is present between the two gates to serve as a barrier layer for charging and discharging carrier electrons when programming and erasing the flash memory.

An oxide/nitride/oxide (ONO) structure is currently being used for the inter-electrode insulating layer. However, the related art ONO layer is formed by a high temperature process of about 780° C. where an oxide, a nitride, and another oxide are formed in sequence in order to form a layer of good quality.

In other words, according to the related art, the ONO structure is formed by sequentially performing a deposition of the oxide film of good quality using a high-temperature oxide, a deposition of a thermal nitride, and a deposition of a high temperature oxide (HTO) thereon.

However, when forming the ONO in the existing manner, there is difficulty in repeatedly performing the unit process three times. In addition, the program characteristics of the flash memory device can be deteriorated from impurities infiltrating the ONO interface occurring due to a generation of interval time for each unit process.

### BRIEF SUMMARY

Embodiments of the present invention provide a flash memory device and a fabricating method thereof capable of simplifying a unit process and improving the characteristics of an ONO interface, when forming an oxide-nitride-oxide (ONO) of a flash memory device.

A flash memory device according to an embodiment comprises: a tunnel insulating layer on a substrate; a floating gate on the tunnel insulating layer; ONO layers on the floating gate; and a control gate on the ONO layers. The ONO layers include a first oxide film, a nitride film, and a second oxide film, where the nitride film is formed by nitriding a vertically intermediate region of a single oxide film thereby forming the first oxide film and second oxide film respectively above and below the nitride film.

Also, a fabricating method of a flash memory device according to an embodiment comprises: forming a tunnel insulating layer on a substrate; forming a floating gate on the tunnel insulating layer; forming an ONO layer by forming an oxide Film on the floating gate and nitriding a vertically intermediate region of the oxide film; and forming a control gate on the ONO layer. The nitride film can be formed in the vertically intermediate region of the oxide film by an annealing process of the substrate.

### BRIEF DESCRIPTION OF THE DRAWINGS

FIG. 1 is a cross-sectional view of a flash memory device according to an embodiment of the present invention; and

FIGS. 2 to 6 are cross-sectional views of a fabricating method of a flash memory device according to an embodiment of the present invention.

### DETAILED DESCRIPTION

Hereinafter, a flash memory device and a fabricating method thereof according to an embodiment of the present invention will be described with reference to the accompanying drawings.

In the description of embodiments, it will be understood that when a layer (or film) is referred to as being ‘on’ another layer or substrate, it can be directly on another layer or substrate, or intervening layers can also be present. Further, it will be understood that when a layer is referred to as being ‘under’ another layer, it can be directly under another layer, or one or more intervening layers can also be present. In addition it will also be understood that when a layer is referred to as being ‘between’ two layers, it can be the only layer between the two layers, or one or more intervening layers can also be present.

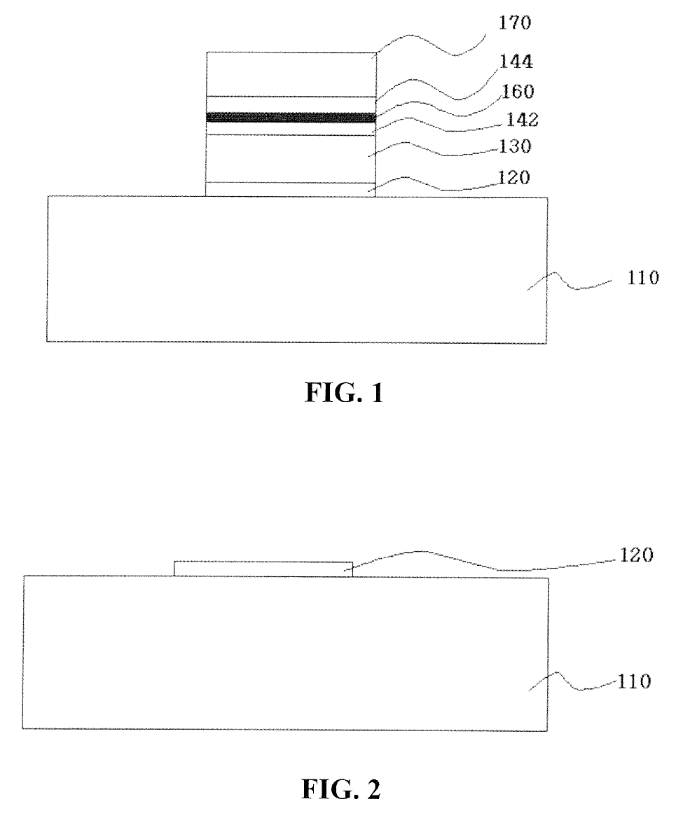

FIG. 1 is a cross-sectional view of a flash memory device according to an embodiment of the present invention.

The memory device according to an embodiment includes a tunnel insulating layer 120 formed on a substrate 110; a floating gate 130 formed on the tunnel insulating layer 120; ONO layers 142, 160, and 144 formed on the floating gate 130; and a control gate 170 formed on the ONO layers 142, 160, and 144. The ONO layers 142, 160, and 144 are a First oxide film 142, a nitride film 160, and a second oxide film 144. The nitride film 160 of the ONO layers can be Formed by nitriding a vertically intermediate region of a single oxide film 140 (see FIG. 4).

At this time, the first oxide film 142 and the second oxide film 144 can have a same physical property being formed of the one oxide film 140.

In other words, according to an embodiment, there is little to no risk of the infiltration of impurity between the first oxide film 142, the second oxide film 144, and the nitride film 160 from the method of forming the ONO by implanting a large quantity of nitrogen (N) into a single oxide film 140 with a plasma nitridation process and performing a subsequent rapid thermal processing anneal (RTP anneal). This method can make it possible to remarkably improve the characteristics of the ONO interface.

Also, the ONO layer (142, 160, and 144) can be formed at a thickness range of about 140 to 220 Å. For example, the first oxide film 142 can have a thickness of about 40-60 Å, the nitride film 160 can have a thickness of about 60-80 Å, and the second oxide film 144 can have a thickness of about 60-80 Å.

With the embodiment, when forming the ONO layers, the process for forming oxide film 140 and the nitridation process are performed once so that the thickness of each layer constituting the ONO layer can finely be controlled.

In one embodiment, the nitride film 160 can be SiON. The nitride film 160 can be made into a SiON by means of nitrogen plasma processing on an oxide film.

Hereinafter, a fabricating method of a flash memory device according to an embodiment of the present invention will be described.

FIGS. 2 to 6 are cross-sectional views of a fabricating method of Rash memory device according to an embodiment.

Referring to FIG. 2, a tunnel insulating layer 120 can be formed on a substrate 110.

In one embodiment, the tunnel insulating layer 120 can be formed by supplying O₂ to the substrate 110 at a temperature of 800 to 1000° C. for several hours.

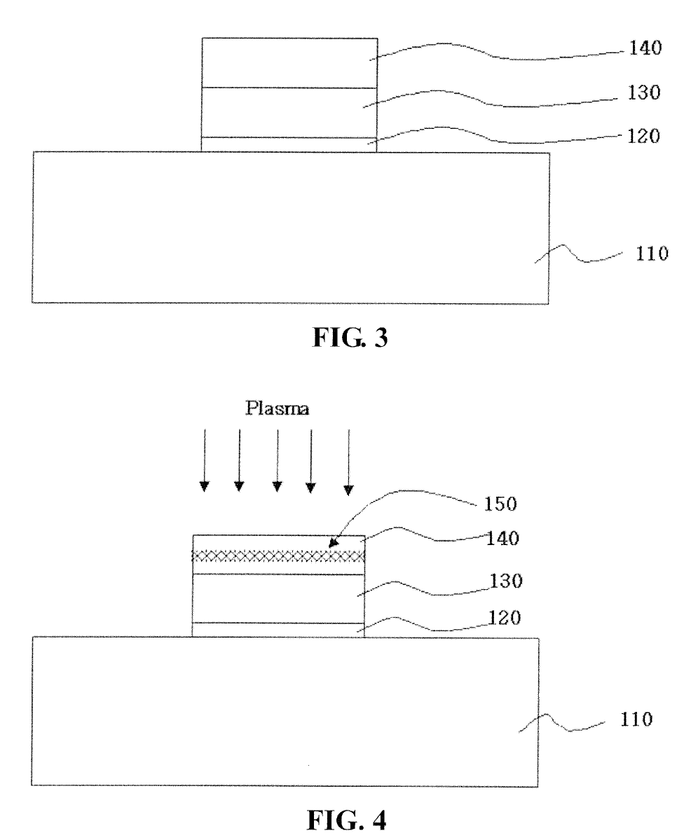

Next, referring to FIG. 3, a floating gate 130 can be formed on the tunnel insulating layer 120.

Thereafter, an oxide film 140 is formed on the floating gate 130.

At this time, the oxide film 140 can be formed at a thickness of about 140 to 220 Å.

Because the nitride Film 160 is ultimately formed in the vertically intermediate region of the oxide film 140 through the nitridation process 150, the thickness of the oxide film 140 can be the thickness of the final ONO layers.

Referring to FIG. 4, a nitridation process 150 on the intermediate region of the oxide film 140 can be performed by means of a plasma processing using the intermediate region of the oxide film 140 as an endpoint.

In one embodiment, the plasma processing can be performed using an RF-power range of 100 to 300 W and a pressure range of 5 to 20 mtorr at room temperature under N₂ ambient of 100 to 300 sccm for 100 to 200 seconds,

For example, the plasma processing can be performed at RF-power of about 200 W, at pressure of about 10 mtorr, and at room temperature under N₂ ambient of 200 sccm for 115 seconds.

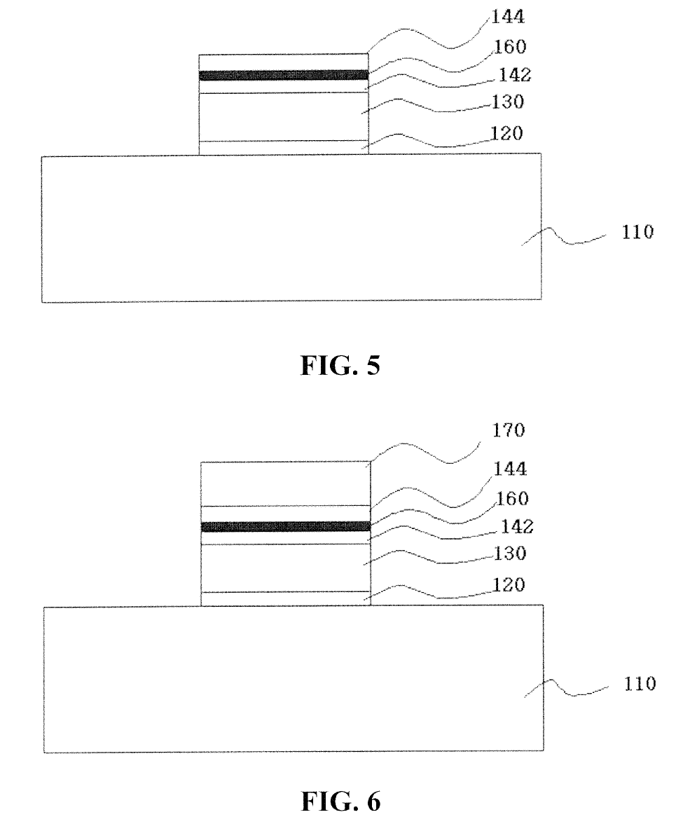

Next, referring to FIG. 5, the substrate 110 comprising the nitrided oxide film 140 is annealed to form the nitride film 160 in the vertically intermediate region of the oxide film 140, so that the ONO layers are formed.

With the embodiment, in the formation of the ONO structure of the flash memory device, the unit process of forming the ONO is remarkably simplified by means of a method of forming the ONO by implanting a great quantity of nitrogen (N) into an oxide film with the plasma nitridation process and performing a subsequent rapid thermal processing anneal (RTP anneal). Accordingly, it possible to shorten the overall process time.

In one embodiment, the step of forming the ONO layer is made by performing a spike annealing on the substrate 11)0 having the nitrided oxide film 140 such that the nitride film 160 is formed in the intermediate region of the oxide film 140.

The spike annealing can be performed at a temperature range of 900 to 1100° C. at a pressure range of 2 to 10 torr, and under an N₂ ambient of 3 to 10 slm (standard liter per minute) and an O₂ ambient of 0.1 to 2 slm for 10 to 20 seconds so that the nitride film 160 can uniformly be formed.

For example, the spike annealing can be performed at a temperature of about 1000° C., at pressure of 5 torr, and under ambient of N₂ of about 4.5 slm (standard liter per minute) and O₂ of 0.5 slm for about 15 seconds to uniformly form the nitride film 160.

Also, in the ONO layer of an embodiment, the first oxide film 142 can be about 40˜60 Å thick, the nitride film 160 can be about 60˜80 Å thick, and the second oxide film 144 can he about 60˜80 Å thick.

With the embodiment, when forming the ONO layer, the process of forming the oxide film 140 and the nitridation process each is performed once so that the thickness of each layer constituting the ONO layers can finely be controlled.

The nitride film 160 in the ONO layer can be SiON. The nitride film 160 can be made into a SiON by means of the nitrogen plasma processing on the oxide film 140.

After forming the ONO layer, a control gate 170 can be formed on the ONO layer. The control gate can be formed using a metal such as aluminum (Al).

According to embodiments of the present invention, the high-temperature oxidation process and the high-temperature nitridation process of the related art can be omitted so that the deterioration of the device can be relieved.

A source/drain (not shown) region can be further formed within the substrate 110 at sides of the floating gate 130 so that the flash memory device according to an embodiment can be completed.

As described above, the flash memory device and the fabricating method thereof according to embodiments of the present invention simplifies the formation of the ONO structure of the flash memory device. The unit process of forming the ONO is remarkably simplified by means of a method of forming the ONO by implanting a great quantity of nitrogen (N) into a high temperature oxide film (IITO) with the plasma nitridation process and performing a subsequent rapid thermal processing anneal (RTP anneal), making it possible to shorten the overall process time.

Also, there is minimal risk of the infiltration of impurity between the high-temperature oxide film and the nitride film by means of a method of forming the ONO by implanting a great quantity of nitrogen (N) with the plasma nitridation process and performing the subsequent rapid thermal processing anneal (RTP anneal), after depositing the oxide film (HTO), making it possible to remarkably improve the characteristics of the ONO interface.

Also, the high-temperature oxidation process and the high-temperature nitridation process of the related art can be omitted so that the deterioration of the device can be relieved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flash memory device, comprising:
a tunnel insulating layer on a substrate;
a floating gate on the tunnel insulating layer;
an ONO layer on the floating gate; and
a control gate on the ONO layer;
wherein the ONO layer comprises a first oxide film, a nitride film, and a second oxide film formed from a single oxide film, wherein the nitride film comprises a nitrided vertically intermediate region of the single oxide film.

2. The flash memory device according to claim 1, wherein the first oxide film and the second oxide film have a same physical property.

3. The flash memory device according to claim 1, wherein the ONO layer has a thickness of 40 to 220 Å.

4. The flash memory device according to claim 3, wherein the first oxide film has a thickness of about 40˜60 Å, the nitride film has a thickness of about 60˜80 Å, and the second oxide film has a thickness of about 60˜80 Å.

5. The flash memory device according to claim 1, wherein the nitride film comprises SiON.

6. A method of fabricating a flash memory device, comprising:
forming a tunnel insulating layer on a substrate;
forming a floating gate on the tunnel insulating layer;
forming an oxide film on the floating gate;
nitriding a vertically intermediate region of the oxide film;
annealing the substrate to form an ONO layer from the oxide film having a nitrided vertically intermediate region; and
forming a control gate on the ONO layer.

7. The method according to claim 6, wherein nitriding the vertically intermediate region of the oxide film comprises performing a plasma processing using the vertically intermediate region of the oxide film as an end point.

8. The method according to claim 7, wherein the plasma processing is performed at RF-power range of 100 to 300 W, pressure range of 5 to 20 mtorr, and at room temperature under N₂ ambient of 100 to 300 seem for 100 to 200 seconds.

9. The method according to claim 6, wherein forming the oxide film on the floating gate forms the oxide film at a thickness of 140 to 220 Å.

10. The method according to claim 6, wherein annealing the substrate comprises performing a spike annealing.

11. The method according to claim 10, wherein annealing the substrate comprises performing the spike annealing at a temperature range of 900 to 1100° C., at a pressure range of 2 to 10 torr and under an N₂ ambient of 3 to 10 slm (standard liter per minute) and an O₂ ambient of 0.1 to 2 slm for 10 to 20 seconds.

12. The method according to claim 6, wherein the ONO layer comprises a first oxide film having a thickness of about 40˜60 Å, a nitride film having a thickness of about 60˜80 Å, and a second oxide film having a thickness of about 60˜80 Å.

13. The method according to claim 6, wherein a nitride film of the ONO layer comprises SiON.
